(19) United States
(12) Patent Application Publication
(10) Pub. No.: US 2024/0282589 A1
(43) Pub. Date: Aug. 22, 2024

(54) SEMICONDUCTOR DEVICES AND METHODS OF MANUFACTURING THEREOF

(71) Applicant: Taiwan Semiconductor Manufacturing Company, Ltd., Hsinchu (TW)

(72) Inventors: Han-Hsiang Huang, Hsinchu (TW); Chun-Hsien Wen, Hsinchu (TW); Ting-Yu Yeh, Hsinchu (TW); Chih-Wei Chang, Hsinchu (TW)

(73) Assignee: Taiwan Semiconductor Manufacturing Company, Ltd., Hsinchu (TW)

(21) Appl. No.: 18/329,356

(22) Filed: Jun. 5, 2023

Related U.S. Application Data
(60) Provisional application No. 63/446,745, filed on Feb. 17, 2023.

(51) Int. Cl. H01L 21/48; H01L 23/00; H01L 23/498

(52) U.S. Cl. CPC H01L 21/4857; H01L 23/49822; H01L 24/81; H01L 2224/81801

(57) ABSTRACT

A method includes providing a semiconductor chip with a plurality of first connector structures disposed on a topmost one of a plurality of metallization layers. The method includes forming a redistribution structure comprising a plurality of conductive layers and a plurality of via structures, adjacent ones of the plurality of conductive layers being connected through at least a corresponding one of the plurality of via structures. The method includes bonding the plurality of first connector structures to the redistribution structure. The method includes bonding the redistribution structure to a carrier substrate through a plurality of second connector structures. Forming the redistribution structure includes laterally rotating a first one of the plurality of via structures around a second one of the plurality of via structures, the first via structure being vertically above the second via structure.

### CROSS-REFERENCE TO RELATED APPLICATION

This application claims the benefit of and priority to U.S. Provisional Application No. 63/446,745, filed Feb. 17, 2023, titled “ADAPTIVE INFO PG DESIGN FOR VARIABLE BUMP PITCH,” which is incorporated herein by reference in its entirety.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example flow chart of a method for fabricating a semiconductor device, in accordance with some embodiments.

FIGS. 2, 3, 4, 5, 6, 7A, 7B, 7C, 8, 9A, 9B, 9C, 9D, 9E, 9F, and 9G illustrate top and cross-sectional views of an example semiconductor device during various fabrication stages, made by the method of FIG. 1, in accordance with some embodiments.

FIG. 10 is an example flow chart of a method for fabricating a semiconductor device, in accordance with some embodiments.

FIGS. 11, 12, 13, 14, 15, and 16 illustrate cross-sectional views of an example semiconductor device during various fabrication stages, made by the method of FIG. 10, in accordance with some embodiments.

FIGS. 17, 18, and 19 illustrate various example packaged semiconductor devices including the disclosed redistribution structure, in accordance with some embodiments.

FIG. 20 illustrates a flowchart of a method of manufacturing a semiconductor device, in accordance with some embodiments.

FIG. 21 illustrates a block diagram of a system of generating an layout design, in accordance with some embodiments.

FIG. 22 illustrates a block diagram of a manufacturing system, and a manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, semiconductor devices can include semiconductor chips connected to terminals through redistribution layers. The semiconductor chips can include data signals, clock signals, strapping inputs, and the like along with power signals. The power signals can include one or more reference voltages or grounds which are referred to herein as VSS along with one or more power rail voltage levels which may be referred to herein as VDD. The VDD and VSS signals can pass through a redistribution structure having one or more redistribution layers (RDLs). The RDL structure can connect from the semiconductor chips along various signal pathways which may each be associated with various voltage profiles acceding to current (I) passed through resistive signal paths (R) (e.g., IR losses). The IR losses can increase thermal losses of a semiconductor device, which can limit device performance. Moreover, the IR losses may impact a stability of a VCC level of the semiconductor chip which may, in turn, affect device performance such as realizing a lower F_max, or may result in erroneous values registered by a transistor of a logic or memory device.

Electronic design automation (EDA) tools can employ extensive analysis of connections to semiconductor pads or terminals. For example, predefined patterns may be employed having a predefined relationships between various layers of the semiconductor device (e.g., various layers of the RDL structure). However, modern semiconductor device may use various semiconductor chips in various packages (e.g., according to a standardized package, or to match a footprint of another semiconductor device). Thus, it may be desirable to adjust a relative location of a connector connecting to a semiconductor package and another connector to interface with a semiconductor chip. For example, one connection can interface with a further substrate including a printed circuit board assembly (PCBA). Thus it is both desirable to characterize the IR performance of connections, and to enable adjustability of an interconnection structure geometry. According to systems and methods of the present disclosure, via structures can be predefined for a first portion of layers of a redistribution structure of a semiconductor device, and adjustable for a second portion of layers of the redistribution structure. By rotating a via structure of an adjustable portion relative to a fixed via structure of a predefined portion, the IR characteristics of the signal path can be substantially maintained while permitting a relative adjustment between the respective connections of the semiconductor device.

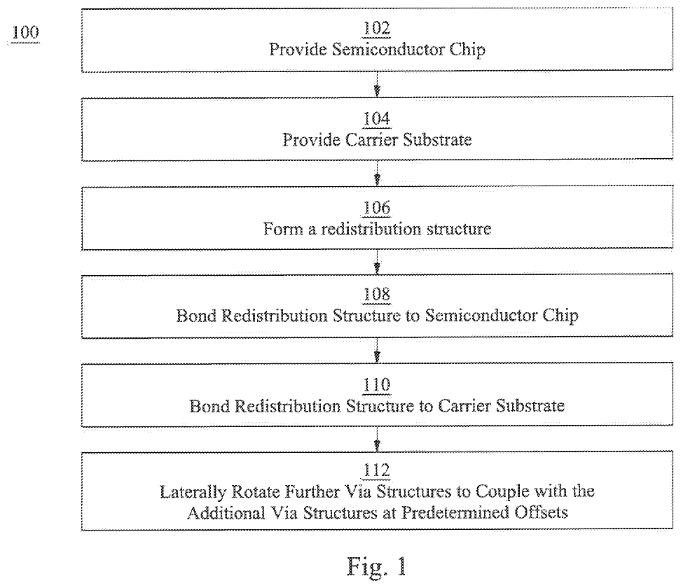

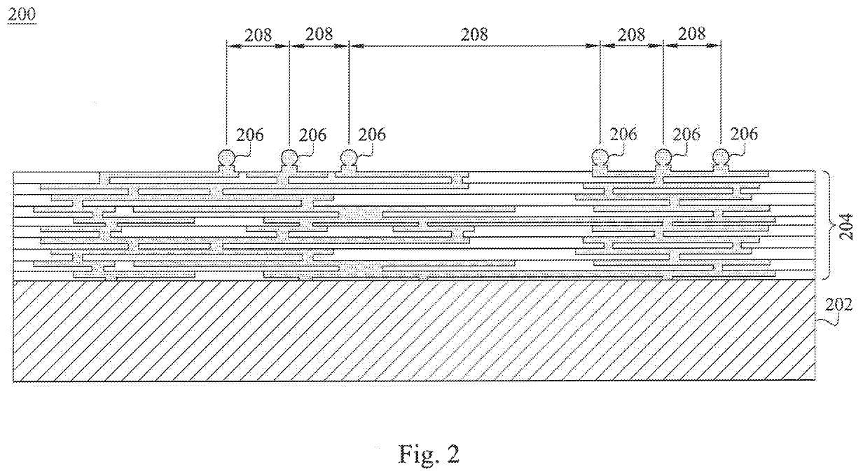

FIG. 1 includes a flowchart of a method 100 of fabricating a semiconductor device, in accordance with some embodiments. For example, at least some of the operations described in the method 100 may result in the semiconductor devices depicted in FIGS. 2-9F. The disclosed method 100 is disclosed as a non-limiting example, and additional operations may be provided before, during, and after the method 100 of FIG. 1. Further, some operations may only be described briefly herein, however, one skilled in the art will understand that the disclosed operations may be performed in conjunction with other disclosed methods disclosed herein, or generally known in the art. For example, one skilled in the art will understand that the semiconductor device may be connected to an intermediate substrate, and that an under-fill be inserted between the semiconductor device and the intermediate substrate, such that the intermediate substrate may be configured to be attached to a PCB, or that the methods and systems provided herein can connect multiple semiconductor chips of a semiconductor device, or connect terminal portions such as in the case of an intermediate substrate, absent any explicit disclosure. Further, the order of the disclosed operations is not intended to be limiting; certain operations may be performed in a different sequence, and still further operations may be sequenced with appropriate modifications thereto. Further, various operations may be performed in one sequence by an EDA tool incident to a routing of various nets of a semiconductor device, and certain operations may thereafter be performed in a different sequence or omitting operations during a physical manufacturing process.

In brief summary, the method 100 includes operation 102, wherein a semiconductor chip is provided for the semiconductor device. The method 100 further includes operation 104 wherein a carrier substrate is provided. At operation 106, a redistribution structure is formed. Operation 108 comprises joining the redistribution structure with the semiconductor chip. Operation 110 comprises joining the redistribution structure with the carrier substrate. At operation 112, some via structures are laterally rotated to couple with other via structures of the redistribution layer.

Corresponding to operation 102 of the method 100 of FIG. 1, FIG. 2 is a cross sectional view of a semiconductor chip 200. The semiconductor chip 200 can include a semiconductor die 202. The semiconductor die 202 can be a semiconductor substrate such as a polysilicon wafer with an active surface comprising various doped surfaces. Metallization layers 204 can interconnect respective portions of the active surface to form circuits therebetween. The metallization layers 204 can vary in feature dimensions such that layers proximal to the semiconductor die 202 may be smaller than feature dimensions distal therefrom. The metallization layers 204 can connect to terminals such as micro-bumps, copper pillars, or another connection structure 206 along an opposite face of the metallization layers 204 than the semiconductor die 202. The connection structure 206 can include various conductive materials such as copper, lead, silver, tin, aluminum, or the like. According to various embodiments, various numbers of metallization layers 204 can be employed (e.g., according to a complexity or density of circuits on an active face of the semiconductor die 202). For example, in some embodiments, about 15 metalization layers can be employed.

The connection structures 206 can include various chip terminal spacings 208 therebetween. For example, the semiconductor chip 200 can include a repeating pattern of landings, micro-bumps, pillars, bond wires, or the like. As depicted, the semiconductor device can include or interface with a predefined pattern of bumps having a same or different signals. For example, the depicted pattern of three micro-bump connection structures 206 with a same spacing 208 therebetween can be repeated for various nets of the semiconductor chip 200. In some embodiments, three of the depicted micro-bump connection structures 206 can be a same power net supplying a voltage such as a VCC net and another three of the depicted micro-bump connection structures 206 can be a same power net supplying a voltage such as a VSS net. The spacing 208 between the sets of three micro-bump connection structures 206 can vary between semiconductor chips 200. For example, the micro-bump connection structures 206 can be positioned to reduce resistive losses in the metallization layers 204 by locating the micro-bump connection structures 206 at areas of use along the semiconductor die 202. The sets of three micro-bump connection structures 206 can connect, through the redistribution structure described henceforth, to another portion of a semiconductor device. For example, some semiconductor devices can include standard terminal layouts such that the relative position between the micro-bump connection structures 206 and the device terminals can vary within or between semiconductor devices.

In some embodiments, a semiconductor device can include a plurality of semiconductor chips 200 which can include further connection structures 206. Like the depicted chip terminal spacings 208 within a semiconductor chip 200, chip-chip spacings can vary. Thus, connection structures (e.g., RDL structures) can laterally vary relative between the various connection structures 206 of the various semiconductor dies 202 and other terminals of the semiconductor device, as is further described henceforth.

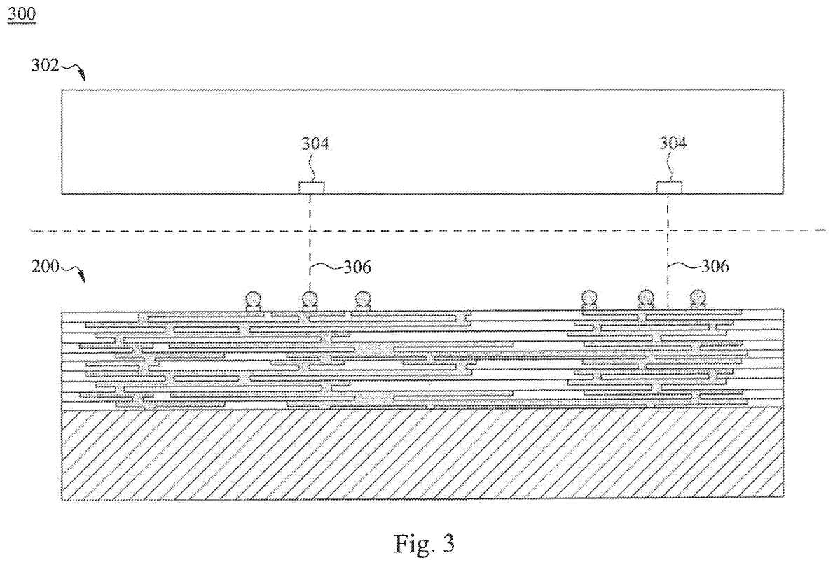

Corresponding to operation 104 of the method 100 of FIG. 1, FIG. 3 is a cross sectional view of a carrier substrate 302. The carrier substrate 302 can be, for example, a PCBA, an interposer, a package substrate, or so forth. In some embodiments, a temporary carrier substrate 302 can be employed and thereafter, the semiconductor device 300 can be debonded therefrom for connection to another carrier substrate 302. The carrier substrate 302 can include terminals 304 configured to receive further connector structures (e.g., BGA ball, C4 balls, or so forth). The terminals 304 can correspond to the connection structures 206 of the semiconductor chip 200 on a 1 to N basis, a 1 to 1 basis, an N to M basis, or an N to 1 basis. For example, the three depicted micro-bump connection structures 206 can each correspond to one terminal 304 of the carrier substrate 302. According to various embodiments, additional or fewer connection structures 206 of the semiconductor chip 200 can correspond to the terminals of the carrier substrate 302. For example, four or six connection structures 206 of the semiconductor chip 200 can correspond to each connection structure of the carrier substrate 302 according to various top views provided henceforth.

As depicted, the terminals 304 can align with a connection structure 206 or a set of connection structures 206. For example, as depicted, the alignments can vary such that some alignment lines 306 may be offset relative to other alignment lines 306. As described henceforth, an RDL structure can adjust a position thereof to electrically connect connection structures 206 of the semiconductor chip 200 with terminals 304 at various offsets.

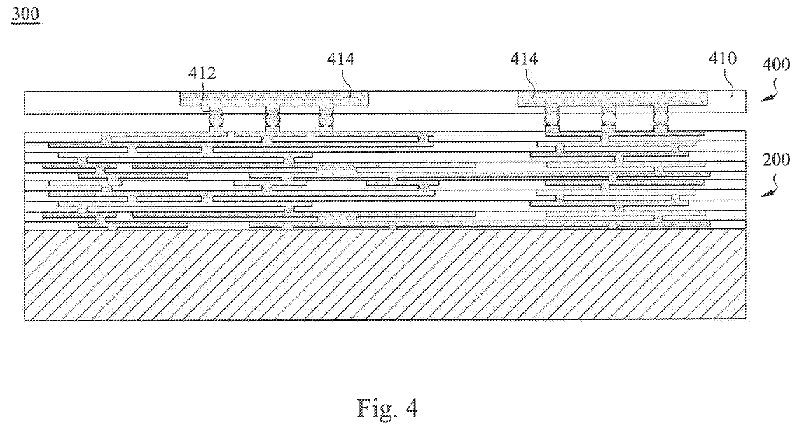

Corresponding to operation 106 and 108 of the method 100 of FIG. 1, FIG. 4 is a cross sectional view of the semiconductor device 300 including the semiconductor chip 200 joined with (e.g., bonded, electrically connected, or so forth) a first layer 410 of a redistribution structure 400. The references to the “first” layer 410 or other “first,” “second,” “third,” elements are merely to distinguish between various portions and are not intended to specify a sequence for the manufacturing or the definition of the layers. For example, the first layer 410 may be formed prior, subsequent, or simultaneous to further layers of the redistribution structure 400. Indeed, according to various embodiments of the present disclosure, the semiconductor device 300 may be manufactured according to a “chip first” process, wherein the RDL structure 400 is formed over a semiconductor chip 200, or a chip last process, wherein the semiconductor chip 200 is deposited over preformed RDL structure 400.

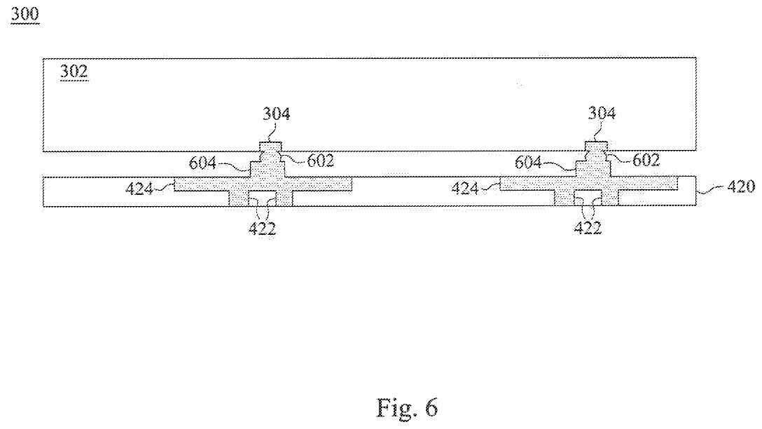

Various portions of the depicted RDL structure 400 are depicted in various figures herein, merely to emphasize features thereof. For example, the RDL layers 410, 420 depicted in FIGS. 4 and 6, respectively may be constituent layers of a redistribution structure 400 wherein other layers are omitted for clarity.

As depicted, the RDL layer 410 includes a plurality of conductive features which may be referred to as conductive layers 414, configured to convey signals laterally along a plane of the semiconductor device 300. The RDL layer 410 may include a plurality of via structures 412 to connect the conductive layers 414 to the connection structure 206 of the semiconductor chip 200. The conductive layer 414 may be further configured to receive (e.g., electrically connect to) further via structures (not depicted) to electrically couple with further conductive layers (not depicted) of the RDL structure 400.

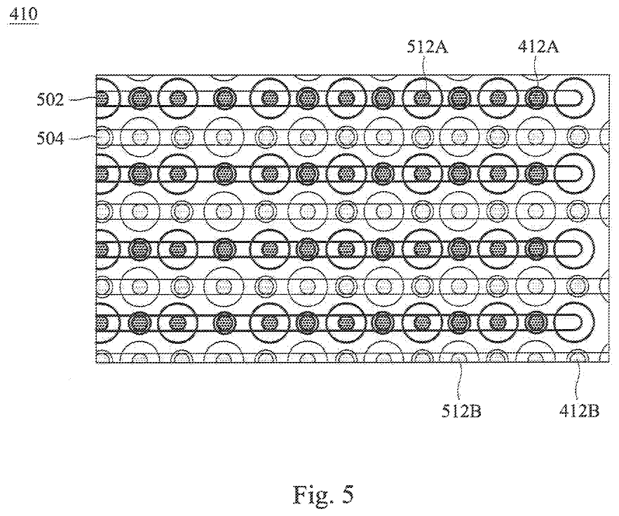

With further correspondence to operation 106, FIG. 5 is a top view of the redistribution layer 410 of the redistribution structure 400 depicted in FIG. 4, coupled to the semiconductor chip 200. A first conductive line 502 conveys a signal (e.g., VDD). A second conductive line 504 conveys another signal, different from the first conductive line 502 (e.g., VSS). As depicted, the redistribution layer 410 can include various such lines which may further include interconnections therebetween. The redistribution layer 410 can include the plurality of via structures 412 depicted in FIG. 4 (e.g., VDD via structures 412A and VSS connection structures 412B). Further, the redistribution layer 410 can include additional via structures 512 to connect the redistribution layer 410 to further redistribution layers 410 (e.g., VDD via structures 512A and VSS connection structures 512B).

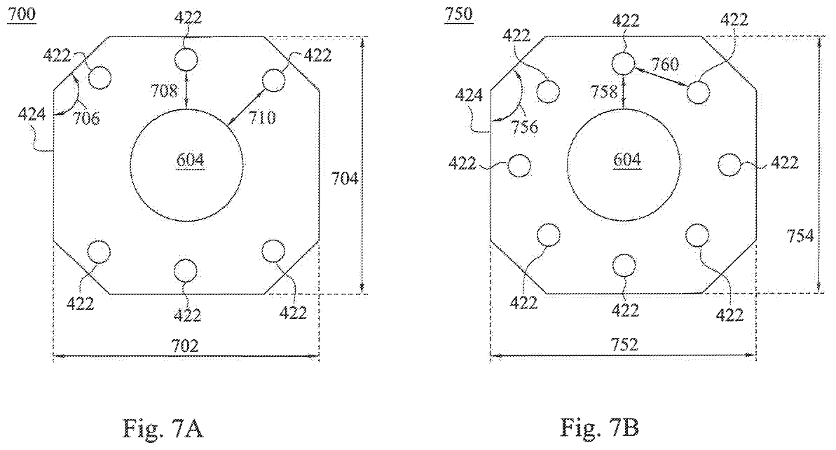

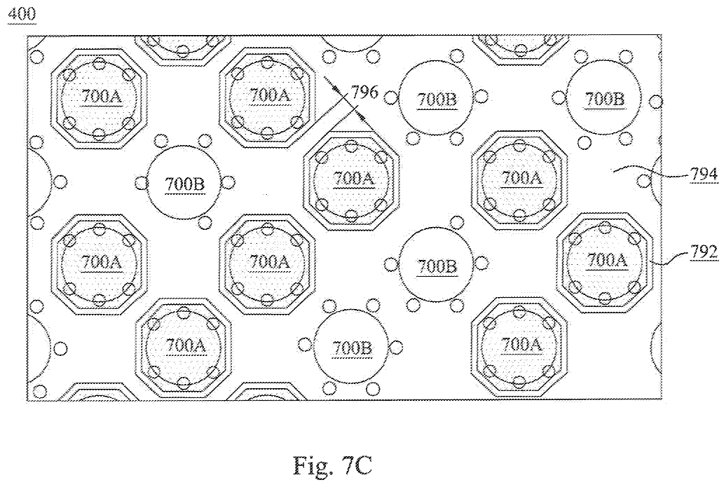

Corresponding to operation 106 and 110 of the method 100 of FIG. 1, FIG. 6 is a cross sectional view of the carrier substrate 302 coupled to a redistribution layer 420 of the redistribution structure 400. As depicted, the terminals 304 of the carrier substrate 302 connect to a second RDL layer 420 via a carrier substrate connection structure 602 (e.g., BGA ball, C4 balls, or so forth). As depicted, another conductive via structure 604 joins the carrier substrate connection structure 602 to a conductive layer 424 of the depicted RDL layer 420. The conductive via structure 604 can be or include a pillar, under-ball metallization structure (UBM), or the like. In some embodiments, the conductive via structure 604 may be omitted such that the carrier substrate connection structure 602 connects directly to a conductive layer 424 of the redistribution structure. Further via structures 422 of the RDL layer extend from the depicted conductive layer 424 in an opposite direction from the carrier substrate 302. Thus, such via structures 422 can connect to the conductive layer 414 depicted in FIG. 4 (e.g., through zero or more intermediating layers of the RDL structure 400, such as five layers thereof). A top view of the geometry of the depicted carrier substrate connection structure 602, conductive via structure 604, conductive layer 424, and further via structures 422, according to some embodiments, is provided henceforth in FIGS. 7A and 7B.

Referring now to FIG. 7A, a top views of the redistribution structure 400 coupled to the carrier substrate 302 is provided. The redistribution structure 400 includes the conductive layer 424 of FIG. 6. More particularly, the conductive layer 424 can include a plurality of the depicted octagonal features 700, each corresponding to a carrier substrate connection structure 602 or via structure 604. The octagonal feature 700 can correspond to a rectangular shape, wherein a width 702 of the octagonal features 700 can be between about 200 μm and about 240 μm (e.g., about 220.695 μm). The features herein can be scaled according to various embodiments. A height 704 of the octagonal features 700 can be between about 190 μm and about 230 μm (e.g., about 210 μm). The corners of the rectangular shape can be pruned at 45° such that a remaining portion of the octagonal feature 700 has an angle 706 of about 135°. For example, a vertical and horizontal pruned distance (as depicted) can be between about 48 μm and 60 μm (e.g., about 53.761 μm). The octagonal features 700 can be a VDD feature in a VSS plane, a VSS feature in a VDD plane, or another power, data, or other signal in various planes. Such dimensional components of the octagonal features 700 can increase a density of such features, relative to other conductive layer 424 geometries.

The via structures 422 depicted as extending from the carrier substrate connection structure 602 or via structure 604 can be spaced therefrom by a distance which can be between 38 μm and 46 μm (e.g., about 42 μm) of the diameter or other dimension of the carrier substrate connection structure 602 or via structure 604. Other via structures 422 can be spaced therefrom by a distance which is can be between about 44 μm and about 54 μm (e.g., about 49 μm). In various embodiments, additional or fewer via structures 422 can connect the depicted octagonal features 700 to adjacent layers of the redistribution structure 400. Further, via structures 422 can be differently disposed within octagonal features 700, or other conductive elements of the conductive layers 424.

Referring now to FIG. 7B, a top view of the redistribution structure 400 coupled to the carrier substrate 302 is provided. More particularly, the conductive layer 424 can include a plurality of the octagonal features 750 different than the octagonal features 750 of FIG. 7A. For example, the depicted octagonal feature 750 can include a height 754 or width 752 of a same dimension as the octagonal feature 700 of FIG. 7A, and include similar perimeter dimensions (e.g., the 135° angle 756 at the corners thereof). As depicted, eight via structures 422 are disposed equilaterally around the carrier substrate connection structure 602 or via structure 604. The via structures 422 may be spaced therefrom, a distance 758 between about 36 μm and 44 μm (e.g., about 40 μm) of the diameter of the carrier substrate connection structure 602 or via structure 604. A spacing 760 between the respective via structures 422 can be between about 42 μm and about 52 μm (e.g., about 47.35 μm).

Referring now to FIG. 7C, a top view of the redistribution structure 400 coupled to the carrier substrate 302 is provided. As depicted, a plurality of octagonal features 700 are disposed along a lateral plane 794 of the redistribution layer 420. A first portion of octagonal features 700A are shown isolated from the plane 794 of the redistribution layer 420. For example, the first portion of octagonal features 700A may be for VDD connections isolated from a ground plane 794 over terminal end of the semiconductor device 300. A second portion of octagonal features 700B are shown integral to the plane 794 of the redistribution layer 420. For example, the second portion of octagonal features 700B may be a same signal as the plane 794 (e.g., VSS). The isolation distance 792 can be constant around the first portion of octagonal features 700A such that a predefined minimum distance 796 between the octagonal features is maintained.

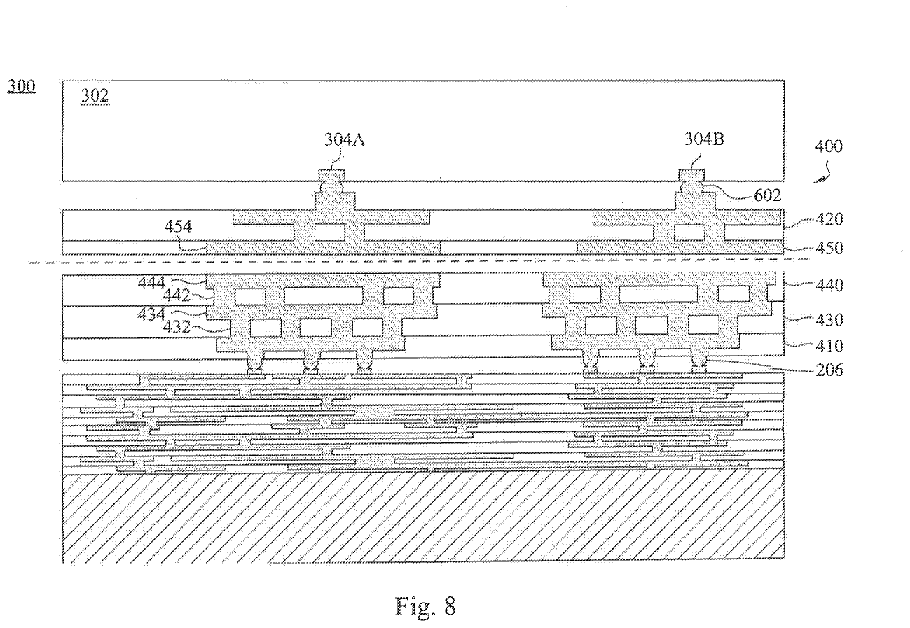

With continued correspondence to operation 106 of FIG. 1, FIG. 8 is a cross sectional view of the redistribution structure 400 coupled to the semiconductor chip 200. Depicted are further layers of the redistribution structure 400. More particularly, a third RDL layer 430, fourth RDL layer 440, and fifth RDL layer 450 are formed, examples of which are further described henceforth. The third redistribution layer 430 can include a predefined conductive layer 434 and via structures 432. The fourth redistribution layer 440 can include a conductive layer 444 which is configurable and predefined via structures 432. The fifth redistribution layer 450 can include a conductive layer 454 which is configurable and configurable via structures 452 (not depicted). For example, a first portion of the conductive layers of the fourth redistribution layer 440 and fifth redistribution layer 450 can be fixed to connect to the second redistribution layer 420 and third redistribution layer 430. A second portion of the corresponding conductive layers 444, 454 can be rotated about the fixed portion to reduce an un-alignment between the semiconductor chip connection structure 206 and carrier substrate connection structure 602. Further top views are provided to depict such rotation henceforth.

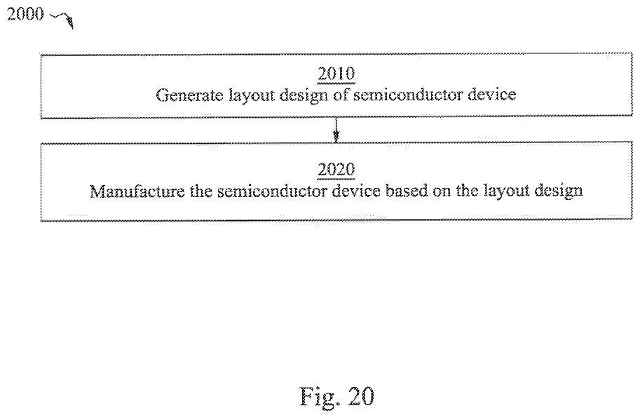

The rotation and various elements of the redistribution structure 400 may refer to a physically assembled device such as copper or tungsten conductive elements overlaying a dielectric layer of a semiconductor device, or representation thereof generated by an electronic design automation (EDA) tool. For example, the EDA tool may rotate vias to form virtual spacings and connections therebetween, and manufacturing systems and devices may thereafter manufacture a device based on a design generated by the EDA tool with the rotated position. A sample flow is provided hereinafter at FIGS. 20, 21, and 22. The connections described herein may include connections formed by a same process (e.g., metal deposition or etching process whereupon a dielectric is formed there over such that the remaining metal portions are embedded in a dielectric material). The rotations described herein may refer to a rotation in an EDA tool, whereupon a manufacturing system can manufacture a physically non-rotatable device. The various elements connecting signals can be formed according to a simultaneous process wherein the various metallic portions of a redistribution layer are formed, and connections therebetween. Indeed, the various processes disclosed herein can be performed in various ordered sequences, including temporally overlapping sequences (simultaneously). In some embodiments, operations disclosed herein may be performed from one surface of the redistribution structure to an opposite surface, or from both surfaces, or iteratively, such that adjustments can be performed and thereafter further adjustments can be performed responsive thereto.

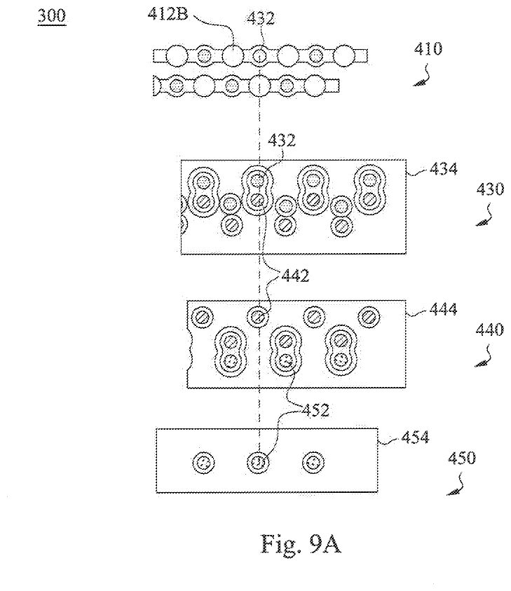

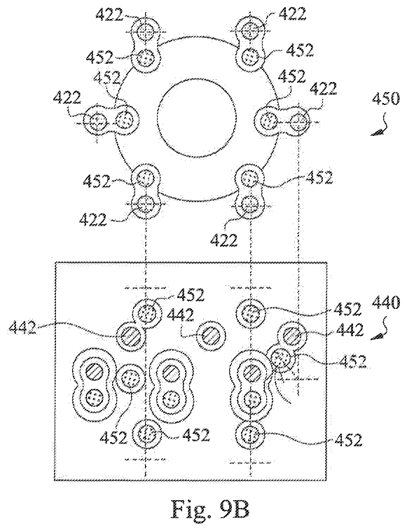

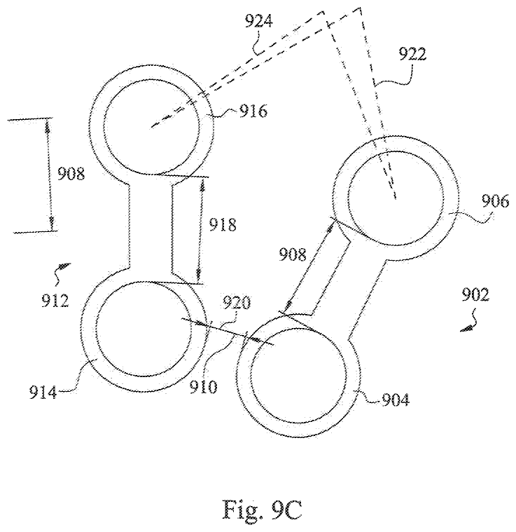

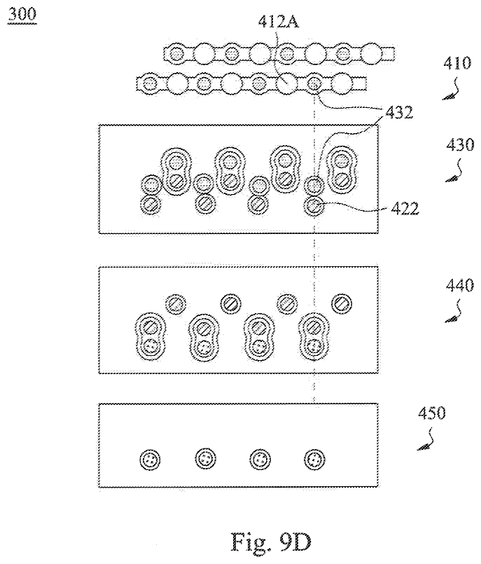

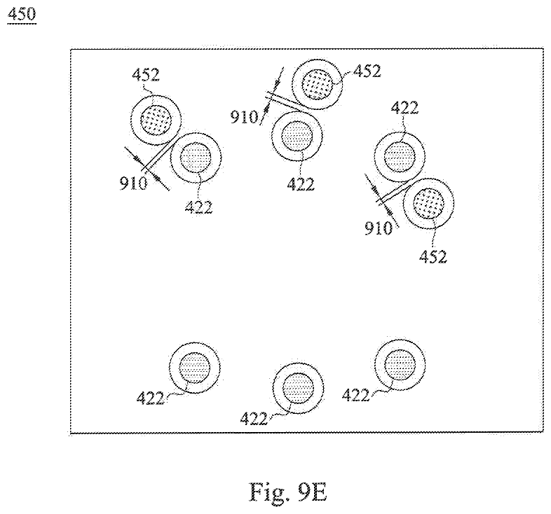

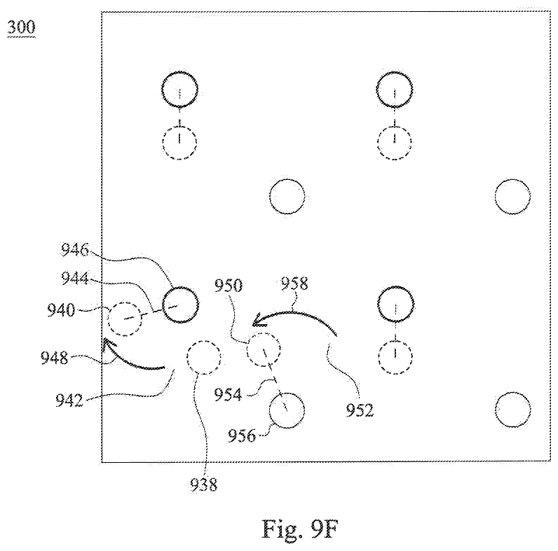

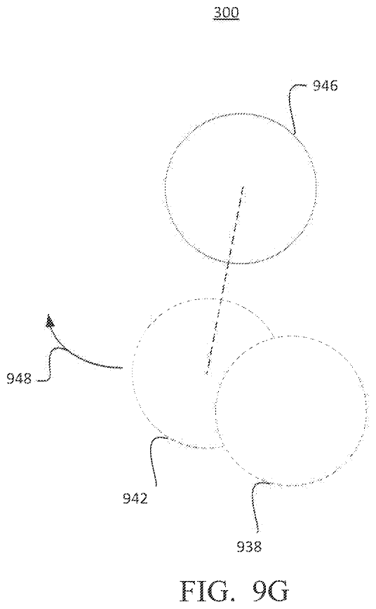

With continued correspondence to operation 106 of the method 100 of FIG. 1, FIG. 9A is an exploded diagram of the layers of redistribution structure 400 of a semiconductor device 300. A via structure 412B connects a signal from the semiconductor chip 200 to a first layer 410 of the RDL structure 400. The via structure 412B laterally connects to a conductive layer 414 (e.g., along the second conductive line 504 of FIG. 5) which, in turn, connects to another via structure 432 extending to a conductive layer 434 of an adjacent RDL layer 430, disposed opposite from the first layer 410. The via structure 432 can be electrically isolated from a plane (e.g., a VDD plane) electrically connecting to a further via structure 442 still to electrically connect to a feature of another adjacent RDL layer 440. For example, the landing location for the via structure 442 may be predefined (e.g., fixed) according to a pattern. The feature may electrically connect to (e.g., be enveloped by) a plane (e.g., a VSS plane). The feature can include a further via structure 452. Such a via may occupy the spacing between the conductive layers 440, 450 shown spaced apart from each other in FIG. 8. The landing location of such a via structure 452 may not be predetermined (e.g., be variable or rotatable) according to the systems and methods herein. The features of the various conductive layers (e.g., 434, 444) can include predefined geometries of a known EMIR characteristic. For example, the size and inter-relative location (relative to each other) may be predetermined for all via structures. The relative location (relative to the carrier substrate 302 or the semiconductor chip 200) may be predefined for at least one via thereof.

Referring now to FIG. 9B, a top view of features of the fourth redistribution layer 440 and fifth redistribution layer 450 are provided. Via structures 422 in the predefined positions of the fifth redistribution layer 450 correspond to the dashed crosses on the fourth redistribution layer 440. The relative position of via structures 452 connecting the fourth redistribution layer 440 and fifth redistribution layer 450 are rotated about the corresponding via structures 422 to a predefined distance from the via structures 452 electrically connected to the plane of the fourth redistribution layer 440. Such a rotation can maintain EMIR characteristics between the paired sets of via structures 422, 452 connecting on the fifth redistribution layer 450, as well as the paired sets of via structures 442, 452 connecting on the fourth redistribution layer.

Referring now to FIG. 9C, a general figure of via structure rotation is provided. The first feature 902 depicts a portion of at least one layer of a redistribution structure 400. A first via 904 and second via 906 are connected by a bridge. A bridge length 908 may be predefined, such as to control EMIR characteristics of a signal path there-through. In some embodiments, the length of the bridge is equal to or double a distance the first feature 902 extends radially around the vias 904, 906, such that the first feature 902 resembles two overlapping or adjacent shapes (e.g., circles).

One via (e.g., the second via 906, as depicted) may be fixed according to a predefined location. The other via (e.g., the first via 904, as depicted) may be freely rotatable there-around. The first via 904 can be rotated to a predefined distance 910 from another element such as a plane, connection, edge, or the depicted second feature 912. The predefined distance 910 may be zero or negative in some embodiments, to electrically connect the first 902 and second features 912. In some embodiments, the second feature may also include or connect to a first via 914 and second via 916 separated by a same or different bridge length 918. The first via 904, 914 of each of the first feature 902 and second feature 912 may be disposed on a same lateral layer of a semiconductor device 300. The second vias 906, 916 may be disposed on lateral layers of the semiconductor device 300 which are adjacent to the layer of the first vias 904, 914, and opposite from each other. According to some embodiments, the rotation can include a rotation of both of the first vias 904, 914.

According to some embodiments, either or both of the first 902 and second features 912 may be connected to or isolated from a plane. For example, the bridge may be integral to a VCC, VDD, or other plane. According to some embodiments, the rotation of the first vias 904, 914 can avoid an obstacle such as a different net. For example each net may have an isolation zone/keep-out distance between nets. The depicted first vias 904, 914 may be rotated such that a center-point 920 between the first vias may be located in a first alternate location 922 or a second alternate location 924, wherein each such location exhibits substantially similar EMIR characteristics as the center-point 920.

Referring now to FIG. 9D, an exploded diagram of the layers of redistribution structure 400 of a semiconductor device 300 is provided. A via structure 412A connects a signal from the semiconductor chip 200 to a first layer 410 of the RDL structure 400. The via structure 412A laterally connects to a conductive layer 414 (e.g., along the first conductive line 502 of FIG. 5) which, in turn, connects to another via structure 432 extending to a conductive layer 434 of an adjacent RDL layer 430, disposed opposite from the first layer 410 from the semiconductor chip 200. The via structure 432 can electrically connect to (e.g., be enveloped by) a plane (e.g., a VDD plane) electrically connecting to a further via structure 442 still to electrically connect to a feature of another adjacent RDL layer 440. For example, the landing location may include a predefined via structure pattern to interface with a connection structure such as the carrier substrate connection structure 602.

Referring now to FIG. 9E, a top view of the conductive layer 450 of FIG. 9D is provided. The location of the via structures 422 depicted in the octagonal feature 700 of FIG. 7A are shown along with the rotatable via structures 452 discussed above. A minimum distance 910 between the various via structures can be controlled such that the EMIR characteristics of the connection between the semiconductor chip 200 and carrier substrate 302 can be normalized. Put differently, by adjusting the relative locations of the depicted via structures, a lateral offset between the semiconductor chip 200 and carrier substrate 302 can be routed with consistent EMIR. For example, the size and inter-relative location (relative to each other) may be predetermined for all via structures. A relative location (relative to the carrier substrate 302 or the semiconductor chip 200) may be rotatable (e.g., not predetermined) for at least one via thereof. For example, the via structure 452 may rotate about an axis defined by the center of another via structure 442 to a predefined distance from yet another via structure 422.

Referring now to FIG. 9F, a top view of various layers of a redistribution structure 400 of a semiconductor device 300 is provided. The various elements are disposed over at least three layers of the semiconductor device 300. For example, a first via 940 disposed on a first layer is rotated from an original position 942 along a first bridge length 944 defined with regard to another via 946 (which may extend to a second layer of the semiconductor device 300). The first via 940 may be rotated to the depicted position thereof by rotating along the depicted rotation line 948. For example, the rotation can move the first via 940 to avoid another via 938 or other feature (e.g., extend to at least a minimum distance therefrom). A second via 950 disposed on the first layer is rotated from an original position 952 along a second bridge length 954 defined with regard to another via still 956 (which may extend to the second layer of the semiconductor device 300 or a third layer, opposite the second layer). The second via 950 may be rotated to the depicted position by rotating along the depicted rotation line 958. For example, the rotation can move the second via 950 to electrically couple with another via 938 or other feature along a geometry distance having predefined EMIR characteristics.

Referring now to FIG. 9G, a detail top view of various layers of a redistribution structure 400 of a semiconductor device 300 is provided. For example the detail top view can depict the same vias as FIG. 9F, prior to a rotation. Particularly, the first via 940 is depicted in an original position overlapping with the other via 938 of a different net. The depicted rotation line 948 indicates a path of travel the via may rotate along to reach the position depicted in FIG. 9F, the rotation line 948 rotating about another via 946.

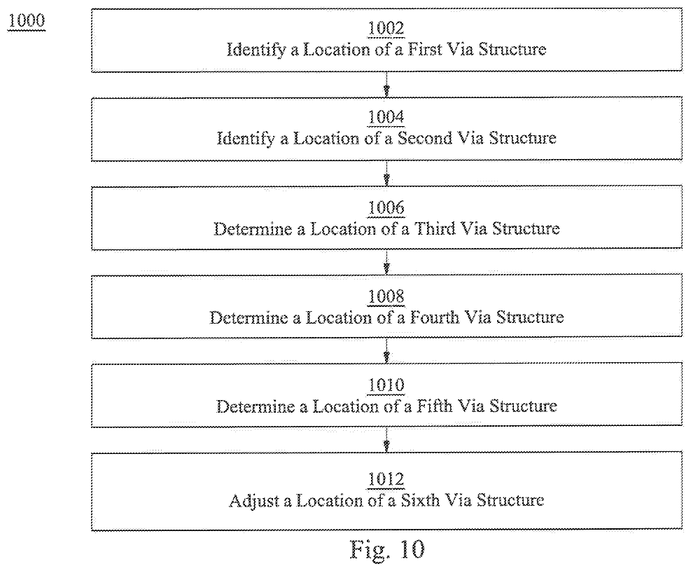

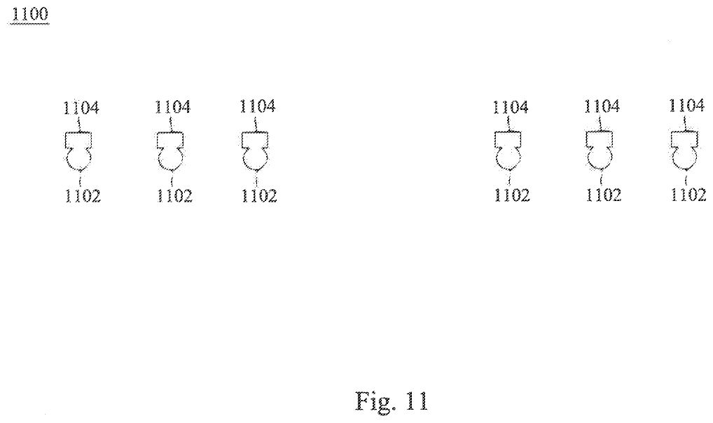

FIG. 10 includes a flowchart of a method 1000 of fabricating a semiconductor device, in accordance with some embodiments. For example, at least some of the operations described in the method 1000 may result in the semiconductor devices depicted in FIGS. 11-16. The disclosed method 1000 is disclosed as a non-limiting example, and additional operations may be provided before, during, and after the method 1000 of FIG. 10. Further, some operations may only be described briefly herein, however, one skilled in the art will understand that the disclosed operations may be performed in conjunction with other disclosed methods disclosed herein, or generally known in the art. Further, the order of the disclosed operations is not intended to be limiting; certain operations may be performed in a different sequence, and still further operations may be sequenced with appropriate modifications thereto.

In brief summary, the method 1000 includes operation 1002, wherein a location of a location of a first via structure is identified. The method 1000 further includes operation 1004 wherein a location of a second via structure is identified. At operation 1006, a location for a third via structure is determined. Operation 1008 comprises determining a location of a fourth via structure. Operation 1010 comprises determining a location for a fifth via structure. At operation 1012, a location of a sixth via structure is adjusted.

Corresponding to operation 1002 of the method 1000 of FIG. 10, FIG. 11 is a cross sectional view of a redistribution structure 1100. A location of a first via structure 1104 is identified. The first via structure 1104 can connect to a first connection structure 1102 such as a terminal connector of a terminal of or interfacing with the redistribution structure 1100. The location can be identified according to a predefined pattern in relation to a first connection structure 1102 (e.g., to a substrate, chip, further interconnect, or the like). In some embodiments, a plurality of first via structures 1104 may be identified which may include a distance therebetween.

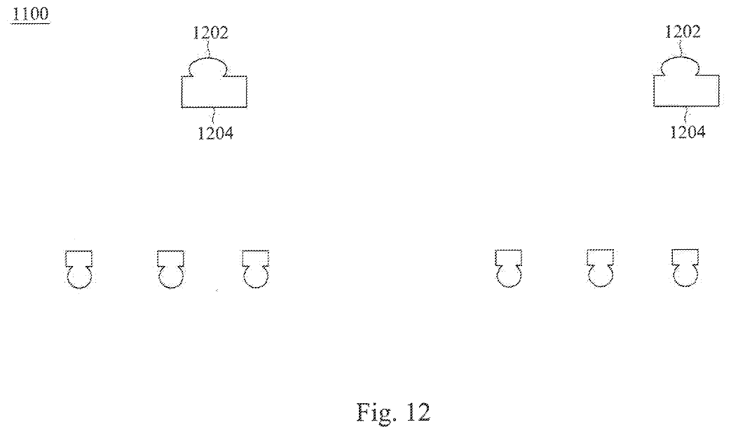

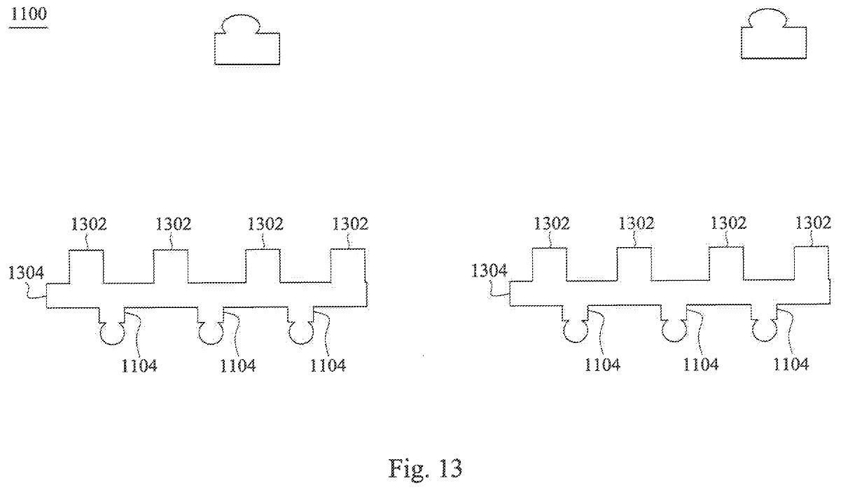

Corresponding to operation 1004 of the method 1000 of FIG. 10, FIG. 12 is a cross sectional view of a redistribution structure 1100. A location of a second via structure 1204 is identified. The second via structure 1204 can connect to a second connection structure 1202 such as a terminal connector of a terminal of or interfacing with the redistribution structure 1100. The location can be identified according to a predefined pattern in relation to the second connection structure 1202 (e.g., to a substrate, chip, further interconnect, or the like). In some embodiments, a plurality of second via structures 1204 may be identified which may include a distance therebetween. The second connection structure 1202 and first connection structure 1102 may be located on opposite sides of a redistribution structure.

Corresponding to operation 1006 of the method 1000 of FIG. 10, FIG. 13 is a cross sectional view of a redistribution structure 1100. A location of a third via structure 1302 is determined. The third via structure 1302 extends upwardly from a first conductive layer 1304. The first via structure 1104 extends downwardly from the first conductive layer 1304. The relative position of the first conductive layer 1304, the third via structure 1302, and the first via structure 1104 may be predefined (e.g., fixed). For example, the first conductive layer 1304 and a third via structure 1302 may be defined based on the via structure 1104 identified at operation 1002.

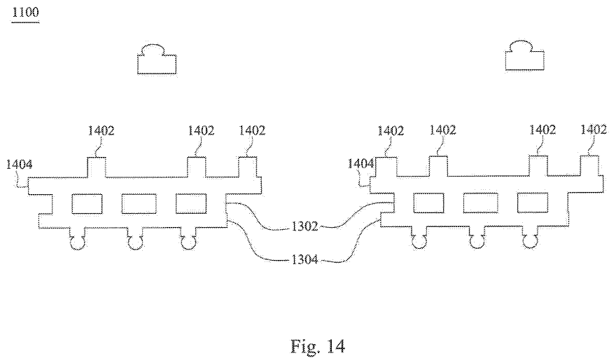

Corresponding to operation 1008 of the method 1000 of FIG. 10, FIG. 14 is a cross sectional view of a redistribution structure 1100. A location of a fourth via structure 1402 is determined. The fourth via structure 1402 extends upwardly from a second conductive layer 1404 to electrically connect the second conductive layer to a vertically spaced conductive layer. The third via structure 1302 extends downwardly from the second conductive layer 1404. The relative position of the second conductive layer 1404, the fourth via structure 1402, and the third via structure 1302 may be predefined (e.g., fixed). For example, the first conductive layer 1304, the third via structure 1302, the second conductive layer 1404, and the fourth via structure 1402 may be defined based on the via structure 1104 identified at operation 1002.

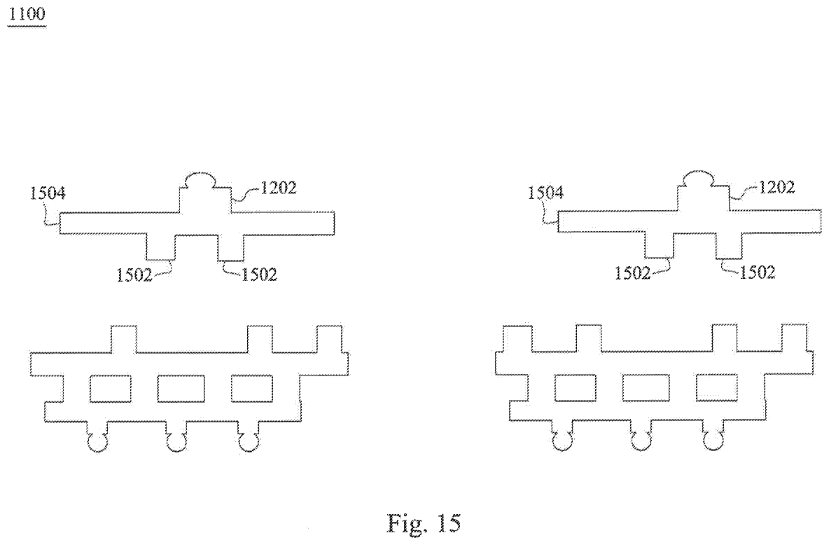

Corresponding to operation 1010 of the method 1000 of FIG. 10, FIG. 15 is a cross sectional view of a redistribution structure 1100. A location of a fifth via structure 1502 is determined. The fifth via structure 1502 extends downwardly from a third conductive layer 1504. The second via structure 1204 extends upwardly from the third conductive layer 1504. The relative position of the third conductive layer 1504, the second via structure 1204, and the fifth via structure 1502 may be predefined according to a predefined pattern (e.g., fixed). For example, the third conductive layer 1504 and the fifth via structure 1502 may be defined based on the second via structure 1204 identified at operation 1004.

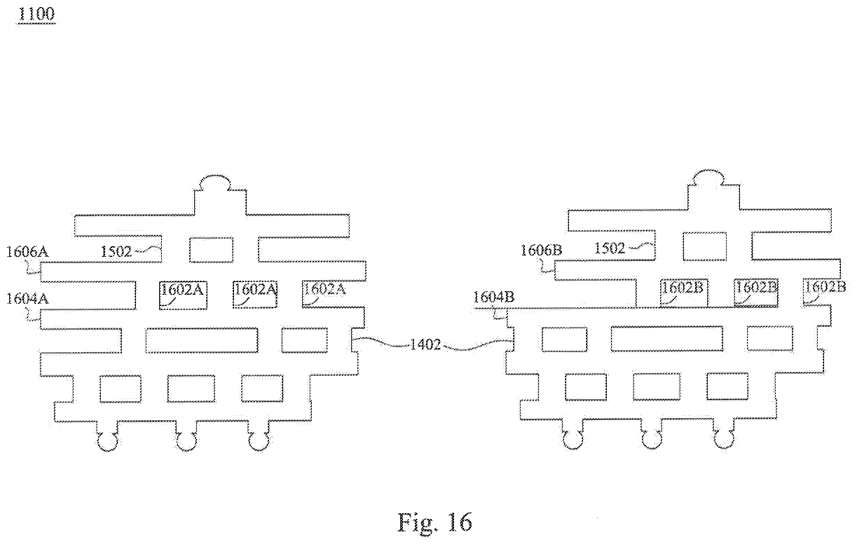

Corresponding to operation 1012 of the method 1000 of FIG. 10, FIG. 16 is a cross sectional view of a redistribution structure 1100. Sixth via structures 1602 can connect a fourth conductive layer 1604 and fifth conductive layer 1606 power of the redistribution structure. The position of the sixth via structures 1602 can be adjusted (e.g., by the EDA tool). The fourth via structure 1402 extends downwardly from the fourth conductive layer 1604. The fifth via structure 1502 extends upwardly from the fifth conductive layer 1606. The sixth via structure 1602 extends upwardly from the fourth conductive layer 1604, and downwardly from the fifth conductive layer 1606.

In some embodiments, the position of the sixth via structures 1602 can be adjusted to connect to (or avoid connecting to) a seventh via structure (not depicted) laterally aligned with the sixth via structure 1602. In some embodiments, the position of the sixth via structures 1602 can be adjusted based on the position of the fourth via structure 1402 (e.g., a portion of the sixth via structures 1602A, fourth conductive layer 1604A, and fifth conductive layer 1606A comprising a VSS net). For example, the sixth via structure 1602 can be rotated to a predefined distance from the fourth via structure 1402 wherein both of the sixth via structure 1602 and the fourth via structure 1402 are electrically connected to a plane of the fourth conductive layer 1604 (e.g., a VSS plane). Likewise, a rotation can separate the sixth via structure 1602 from the fifth conductive layer 1606 (e.g., a VDD plane). In some embodiments, the position of the sixth via structures 1602 can be adjusted based on the position of the fifth via structure 1502 (e.g., a portion of the sixth via structures 1602B, fourth conductive layer 1604B, and fifth conductive layer 1606B comprising a VDD net). For example, the sixth via structure 1602 can be rotated to a predefined distance from the fifth via structure 1502 wherein both of the sixth via structure 1602 and the fifth via structure 1502 are electrically isolated from a plane of the fourth conductive layer 1604 (e.g., a VSS plane). Likewise, a rotation can separate the sixth via structure 1602 from the fifth conductive layer 1606 (e.g., a VDD plane).

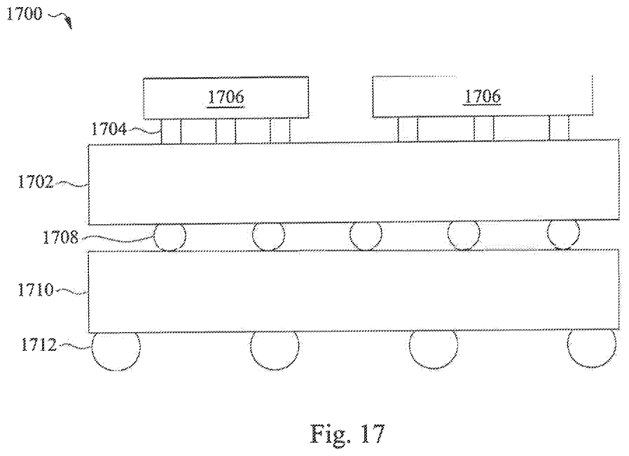

The redistribution structures disclosed herein are not intended to be limiting. For example, additional layers thereof can be formed, different patterns can be formed and so forth. For example, the redistribution structures can join elements of various semiconductor devices. Referring generally to FIGS. 17-19, packages for various semiconductor devices 300 are provided comprising an RDL structure 1100, each structure comprising a plurality of RDL layers. Each RDL structure 1100 can employ the systems and methods described herein. For example, each RDL structure may include a first portion of predefined or fixed via structures and conductive layers, and a second portion of adjustable vias adjusted based on the fixed portions

Referring now to FIG. 17, the package 1700 includes a redistribution structure 1702 having a number of the redistribution layers 400, 1100 discussed above with respect to FIGS. 2-9 and 11-16. The package 1700 includes a number of first connectors 1704 disposed on a first side of the redistribution structure 1702, and a number of second connectors 1708 disposed on a second, opposite side of the redistribution structure 1702. The first connectors 1704 are configured to couple the redistribution structure 1702 to a number of semiconductor dies 1706, and the second connectors 1708 are configured to couple the redistribution structure 1702 to a package substrate 1710. Further, on a side of the package substrate 1710 opposite to the side facing the redistribution structure 1702, the package 1700 includes a number of third connectors 1712. Such a package 1700 may sometimes be referred to as a Chip-on-Wafer-on-Substrate-Redistribution (CoWoS-R) integrated circuit.

In some embodiments, the first/second/third connectors 1704/1708/1712 may be solder balls, metal pillars, controlled collapse chip connection (C4) bumps, micro bumps, electroless nickel-electroless palladium-immersion gold technique (ENEPIG) formed bumps, combination thereof (e.g., a metal pillar having a solder ball attached thereof), or the like. The connectors 1704/1708/1712 may include a conductive material such as solder, copper, aluminum, gold, nickel, silver, palladium, tin, the like, or a combination thereof. In some embodiments, connectors 1704/1708/1712 comprise a eutectic material and may comprise a solder bump or a solder ball, as examples. The solder material may be, for example, lead-based and lead-free solders, such as Pb—Sn compositions for lead-based solder; lead-free solders including InSb; tin, silver, and copper (SAC) compositions; and other eutectic materials that have a common melting point and form conductive solder connections in electrical applications. For lead-free solder, SAC solders of varying compositions may be used, such as SAC 105 (Sn 98.5%, Ag 1.0%, Cu 0.5%), SAC 305, and SAC 405, as examples. Lead-free connectors such as solder balls may be formed from SnCu compounds as well, without the use of silver (Ag). Alternatively, lead-free solder connectors may include tin and silver, Sn—Ag, without the use of copper. The connectors 1704/1708/1712 may form a grid, such as a ball grid array (BGA). In some embodiments, a reflow process may be performed, giving the connectors 1704/1708/1712 a shape of a partial sphere in some embodiments. Alternatively, the connectors 1704/1708/1712 may comprise other shapes.

The connectors 1704/1708/1712 may also comprise non-spherical conductive connectors, for example. In some embodiments, the connectors 1704/1708/1712 comprise metal pillars (such as a copper pillar) formed by a sputtering, printing, electro plating, electroless plating, CVD, or the like, with or without a solder material thereon. The metal pillars may be solder free and have substantially vertical sidewalls or tapered sidewalls.

The connectors 1704/1708/1712 may also include an under bump metallization (UBM) formed and patterned over an uppermost metallization pattern in accordance with some embodiments, thereby forming an electrical connection with an uppermost metallization layer. The UBMs provides an electrical connection upon which an electrical connector, e.g., a solder ball/bump, a conductive pillar, or the like, may be placed. In an embodiment, the UBMs include a diffusion barrier layer, a seed layer, or a combination thereof. The diffusion barrier layer may include Ti, TiN, Ta, TaN, or combinations thereof. The seed layer may include copper or copper alloys. However, other metals, such as nickel, palladium, silver, gold, aluminum, combinations thereof, and multi-layers thereof, may also be included. In an embodiment, UBMs are formed using sputtering. In other embodiments, electro plating may be used.

The semiconductor dies 1706 may each include a main body, an interconnect region, and connectors. The main body may comprise any number of dies, substrates, transistors, active devices, passive devices, or the like. The interconnect region may provide a conductive pattern that allows a pin-out contact pattern for the main body. The connectors may be disposed on a side of each die, and may be used to physically and electrically connect the die to connectors 1704. The connectors may be electrically connected to the main body through the interconnect region. In various embodiments, the semiconductor dies 1706 may each be implemented as a logic die, a memory die, or a combination thereof. Example logic dies include Central Processing Units (CPUs), application processors (APs), system on chips (SOCs), Application Specific Integrated Circuits (ASICs), or other types of logic dies including logic transistors therein. Example memory dies include Dynamic Random Access Memory (DRAM) dies, Static Random Access Memory (SRAM) dies, High-Bandwidth Memory (HBM) dies, Micro-Electro-Mechanical System (MEMS) dies, Hybrid Memory Cube (HMC) dies, or the like.

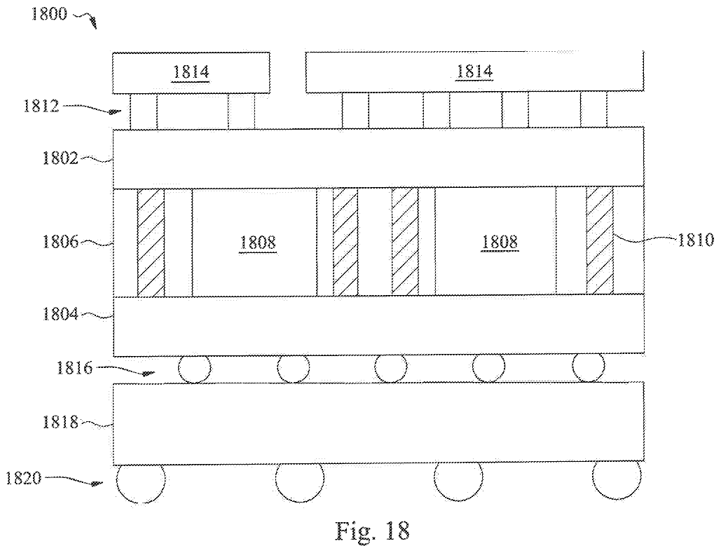

Referring now to FIG. 18, the package 1800 includes a first redistribution structure 1802 and a second redistribution structure 1804, each of which has a number of the redistribution layers discussed above. The package 1800 includes a molding material 1806 with the redistribution structures 1802 and 1804 disposed on its both sides, respectively. The molding material 1806 may include a molding compound, a molding underfill, an epoxy, or a resin. Within the molding material 1806, the package 1800 includes a number of interposers (sometimes referred to as Local Silicon Interconnection (LSI)) 1808 and a number of through vias 1810. The interposer 1808 can provide an increased number of electrical paths, connections, and the like, in a smaller area than would otherwise be possible. The package 1800 includes a number of first connectors 1812 disposed on a side of the first redistribution structure 1802 opposite to the side facing the molding material 1806, and a number of second connectors 1816 disposed on a side of the second redistribution structure 1804 opposite to the side facing the molding material 1806. The first connectors 1812 are configured to couple the first redistribution structure 1802 to a number of semiconductor dies 1814, and the second connectors 1816 are configured to couple the second redistribution structure 1804 to a package substrate 1818. Further, on a side of the package substrate 1818 opposite to the side facing the redistribution structure 1804, the package 1800 includes a number of third connectors 1820. The connectors 1812/1816/1820 may be implemented similarly to the connectors 1704/1708/1712 (FIG. 17), and thus, the discussions are not repeated. Also, the semiconductor dies 1814 may be implemented similarly to the semiconductor dies 1706 (FIG. 17), and thus, the discussion are not repeated. Such a package 1800 may sometimes be referred to as a Chip-on-Wafer-on-Substrate-LSI (CoWoS-L) integrated circuit.

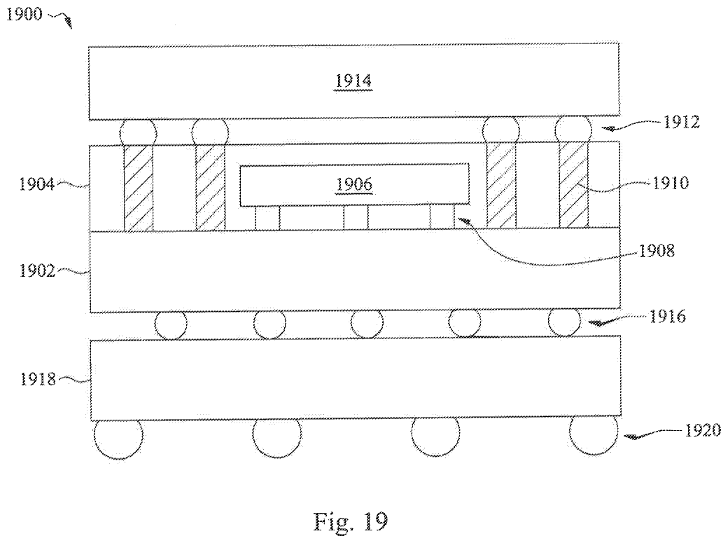

Referring now to FIG. 19, the package 1900 includes a redistribution structure 1902 having a number of the redistribution layers discussed above. The package 1900 includes a molding material 1904 disposed on a side of the redistribution structure 1902. The molding material 1904 may include a molding compound, a molding underfill, an epoxy, or a resin. Within the molding material 1904, the package 1900 includes a first semiconductor die 1906 coupled to the redistribution structure 1902 through a number of first connectors 1908. The package 1900 includes a number of through vias 1910 in the molding material 1904. The package 1900 includes a second semiconductor die 1914 coupled to the redistribution structure 1902 through a number of second connectors 1912, which are coupled to the through vias 1910. On a side of the redistribution structure 1902 opposite to the side facing the molding material 1904, the package 1900 includes a number of third connectors 1916 configured to couple the redistribution structure 1902 to a package substrate 1918. Further, on a side of the package substrate 1918 opposite to the side facing the redistribution structure 1902, the package 1900 includes a number of fourth connectors 1920. The connectors 1908/1912/1916/1920 may be implemented similarly to the connectors 1704/1708/1712 (FIG. 17), and thus, the discussions are not repeated. In some embodiments, the connectors 1908/1912/1916/1920 may not contain any C4 bumps. Also, the semiconductor dies 1906 and 1914 may be implemented as the logic die and the memory die, respectively, discussed above with respect to FIG. 17, and thus, the discussions are not repeated. Such a package 1900 may sometimes be referred to as an Integrated Fan-Out_Package-on-Package (InFo_PoP) integrated circuit.

FIG. 20 is a flowchart of a method 2000 of forming or manufacturing a semiconductor device, in accordance with some embodiments. It is understood that additional operations may be performed before, during, and/or after the method 2000 depicted in FIG. 20. In some embodiments, the method 2000 is usable to form a semiconductor device, according to various layout designs as disclosed herein.

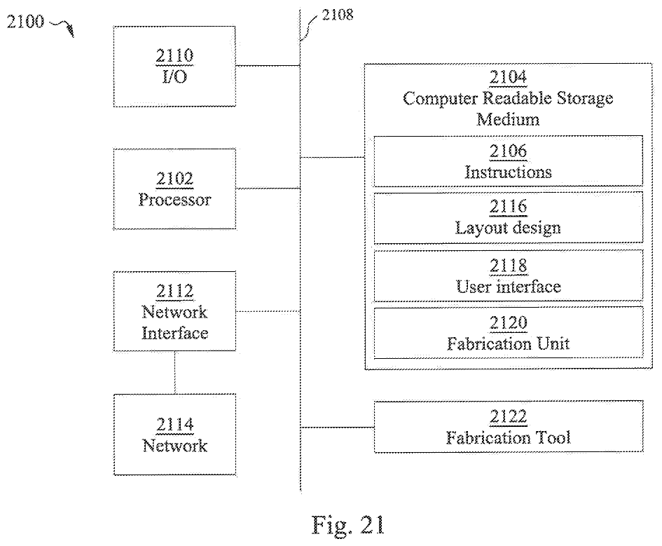

In operation 2010 of the method 2000, a layout design of a semiconductor device (e.g., the layouts of an RDL discussed with respect to FIGS. 1) is generated. The operation 2010 is performed by a processing device (e.g., processor 2102 of FIG. 21) configured to execute instructions for generating a layout design. In one approach, the layout design is generated by placing layout designs of one or more standard cells through a user interface. In one approach, the layout design is automatically generated by a processor executing a synthesis tool that converts a logic design (e.g., Verilog) into a corresponding layout design. In some embodiments, the layout design is rendered in a graphic database system (GDSII) file format. The operation can be performed to include the use of an EDA tool.

In operation 2020 of the method 2000, a semiconductor device is manufactured based on the layout design. In some embodiments, the operation 2020 of the method 2000 includes manufacturing at least one mask based on the layout design, and manufacturing the a semiconductor device based on the at least one mask.

FIG. 21 is a schematic view of a system 2100 for designing and manufacturing an IC layout design, in accordance with some embodiments. The system 2100 generates or places one or more IC layout designs, as described herein. In some embodiments, the system 2100 manufactures one or more semiconductor devices based on the one or more IC layout designs, as described herein. The system 2100 includes a hardware processor 2102 and a non-transitory, computer readable storage medium 2104 encoded with, e.g., storing, the computer program code 2106, e.g., a set of executable instructions. The computer readable storage medium 2104 is configured for interfacing with manufacturing machines for producing the semiconductor device. The processor 2102 is electrically coupled to the computer readable storage medium 2104 by a bus 2108. The processor 2102 is also electrically coupled to an I/O interface 2110 by the bus 2108. A network interface 2112 is also electrically connected to the processor 2102 by the bus 2108. Network interface 2112 is connected to a network 2114, so that the processor 2102 and the computer readable storage medium 2104 are capable of connecting to external elements via network 2114. The processor 2102 is configured to execute the computer program code 2106 encoded in the computer readable storage medium 2104 in order to cause the system 2100 to be usable for performing a portion or all of the operations as described in method 2000.

In some embodiments, the processor 2102 is a central processing unit (CPU), a multi-processor, a distributed processing system, an application specific integrated circuit (ASIC), and/or a suitable processing unit.

In some embodiments, the computer readable storage medium 2104 is an electronic, magnetic, optical, electromagnetic, infrared, and/or a semiconductor system (or apparatus or device). For example, the computer readable storage medium 2104 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer readable storage medium 2104 includes a compact disk-read only memory (CD-ROM), a compact disk-read/write (CD-R/W), and/or a digital video disc (DVD).

In some embodiments, the storage medium 2104 stores the computer program code 2106 configured to cause the system 2100 to perform the method 1400. In some embodiments, the storage medium 2104 also stores information needed for performing method 2000 as well as information generated during performance of method 2000, such as layout design 2116, user interface 2118, fabrication unit 2120, and/or a set of executable instructions to perform the operation of method 2000.

In some embodiments, the storage medium 2104 stores instructions (e.g., the computer program code 2106) for interfacing with manufacturing machines. The instructions (e.g., the computer program code 2106) enable the processor 2102 to generate manufacturing instructions readable by the manufacturing machines to effectively implement the method 2000 during a manufacturing process.

The system 2100 includes the I/O interface 2110. The I/O interface 2110 is coupled to external circuitry. In some embodiments, the I/O interface 2110 includes a keyboard, keypad, mouse, trackball, trackpad, and/or cursor direction keys for communicating information and commands to the processor 2102.

The system 2100 also includes the network interface 2112 coupled to the processor 2102. The network interface 2112 allows the system 2100 to communicate with the network 2114, to which one or more other computer systems are connected. The network interface 2112 includes wireless network interfaces such as BLUETOOTH, WIFI, WIMAX, GPRS, or WCDMA; or wired network interface such as ETHERNET, USB, or IEEE-13154. In some embodiments, the method 2000 is implemented in two or more systems 2100, and information such as layout design, user interface and fabrication unit are exchanged between different systems 2100 by the network 2114.

The system 2100 is configured to receive information related to a layout design through the I/O interface 2110 or network interface 2112. The information is transferred to the processor 2102 by the bus 2108 to determine a layout design for producing an IC. The layout design is then stored in the computer readable medium 2104 as the layout design 2116. The system 2100 is configured to receive information related to a user interface through the I/O interface 2110 or network interface 2112. The information is stored in the computer readable medium 2104 as the user interface 2118. The system 2100 is configured to receive information related to a fabrication unit through the I/O interface 2110 or network interface 2112. The information is stored in the computer readable medium 2104 as the fabrication unit 2120. In some embodiments, the fabrication unit 2120 includes fabrication information utilized by the system 2100.

In some embodiments, the method 2000 is implemented as a standalone software application for execution by a processor. In some embodiments, the method 2000 is implemented as a software application that is a part of an additional software application. In some embodiments, the method 2000 is implemented as a plug-in to a software application. In some embodiments, the method 2000 is implemented as a software application that is a portion of an EDA tool. In some embodiments, the method 2000 is implemented as a software application that is used by an EDA tool. In some embodiments, the EDA tool is used to generate a layout design of the integrated circuit device. In some embodiments, the layout design is stored on a non-transitory computer readable medium. In some embodiments, the layout design is generated using a tool such as VIRTUOSO® available from CADENCE DESIGN SYSTEMS, Inc., or another suitable layout generating tool. In some embodiments, the layout design is generated based on a netlist which is created based on the schematic design. In some embodiments, the method 2000 is implemented by a manufacturing device to manufacture an integrated circuit using a set of masks manufactured based on one or more layout designs generated by the system 2100. In some embodiments, the system 2100 includes a manufacturing device (e.g., fabrication tool 2122) to manufacture an integrated circuit using a set of masks manufactured based on one or more layout designs of the present disclosure. In some embodiments, the system 2100 of FIG. 21 generates layout designs of an IC that are smaller than other approaches. In some embodiments, the system 2100 of FIG. 21 generates layout designs of a semiconductor device that occupy less area or include better EMIR control relative to other approaches.

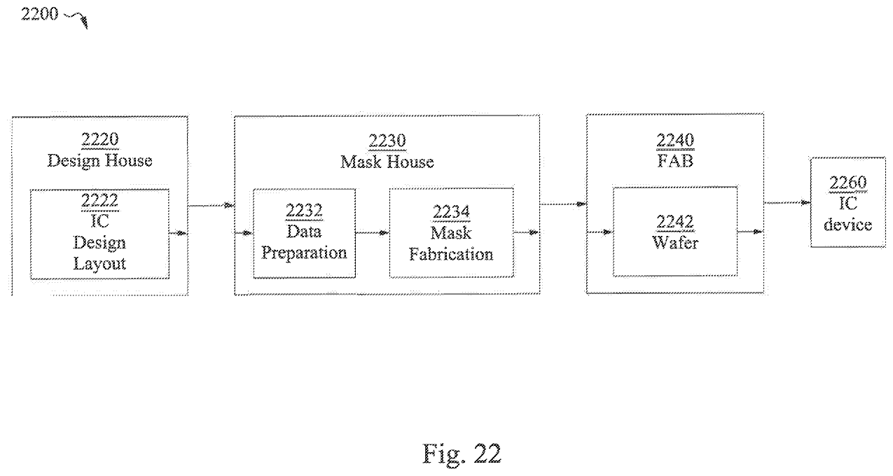

FIG. 22 is a block diagram of an integrated circuit (IC)/semiconductor device manufacturing system 2200, and an IC manufacturing flow associated therewith, in accordance with at least one embodiment of the present disclosure.

In FIG. 22, the IC manufacturing system 2200 includes entities, such as a design house 2220, a mask house 2230, and an IC manufacturer/fabricator (“fab”) 2240, that interact with one another in the design, development, and manufacturing cycles and/or services related to manufacturing an IC device (semiconductor device) 2260. The entities in system 2200 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 2220, mask house 2230, and IC fab 2240 is owned by a single company. In some embodiments, two or more of design house 2220, mask house 2230, and IC fab 2240 coexist in a common facility and use common resources.

The design house (or design team) 2220 generates an IC design layout 2222. The IC design layout 2222 includes various geometrical patterns designed for the IC device 2260. The geometrical patterns correspond to patterns of metal, oxide, or semiconductor layers that make up the various components of the IC device 2260 to be fabricated. The various layers combine to form various IC features. For example, a portion of the IC design layout 2222 includes various IC features, such as an active region, gate structures, source/drain structures, interconnect structures, and openings for bonding pads, to be formed in a semiconductor substrate (such as a silicon wafer) and various material layers disposed on the semiconductor substrate. The design house 2220 implements a proper design procedure to form the IC design layout 2222. The design procedure includes one or more of logic design, physical design or place and route. The IC design layout 2222 is presented in one or more data files having information of the geometrical patterns. For example, the IC design layout 2222 can be expressed in a GDSII file format or DFII file format.

The mask house 2230 includes mask data preparation 2232 and mask fabrication 2234. The mask house 2230 uses the IC design layout 2222 to manufacture one or more masks to be used for fabricating the various layers of the IC device 2260 according to the IC design layout 2222. The mask house 2230 performs the mask data preparation 2232, where the IC design layout 2222 is translated into a representative data file (“RDF”). The mask data preparation 2232 provides the RDF to the mask fabrication 2234. The mask fabrication 2234 includes a mask writer. A mask writer converts the RDF to an image on a substrate, such as a mask (reticle) or a semiconductor wafer, or a metal layer which is formed and thereafter selectively etched to form a redistribution layer at a back end of line process of the fab. The design layout is manipulated by the mask data preparation 2232 to comply with particular characteristics of the mask writer and/or requirements of the IC fab 2240. In FIG. 22, the mask data preparation 2232 and mask fabrication 2234 are illustrated as separate elements. In some embodiments, the mask data preparation 2232 and mask fabrication 2234 can be collectively referred to as mask data preparation.

In some embodiments, the mask data preparation 2232 includes optical proximity correction (OPC) which uses lithography enhancement techniques to compensate for image errors, such as those that can arise from diffraction, interference, other process effects and the like. OPC adjusts the IC design layout 2222. In some embodiments, the mask data preparation 2232 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 2232 includes a mask rule checker (MRC) that checks the IC design layout that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout to compensate for limitations during the mask fabrication 2234, which may undo part of the modifications performed by OPC in order to meet mask creation rules.

In some embodiments, the mask data preparation 2232 includes lithography process checking (LPC) that simulates processing that will be implemented by the IC fab 2240 to fabricate the IC device 2260. LPC simulates this processing based on the IC design layout 2222 to create a simulated manufactured device, such as the IC device 2260. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC can be repeated to further refine the IC design layout 2222.

It should be understood that the above description of the mask data preparation 2232 has been simplified for the purposes of clarity. In some embodiments, the mask data preparation 2232 includes additional features such as a logic operation (LOP) to modify the IC design layout according to manufacturing rules. Additionally, the processes applied to the IC design layout 2222 during the mask data preparation 2232 may be executed in a variety of different orders.

After the mask data preparation 2232 and during mask fabrication 2234, a mask or a group of masks are fabricated based on the modified IC design layout. In some embodiments, an electron-beam (e-beam) or a mechanism of multiple e-beams is used to form a pattern on a mask (photomask or reticle) based on the modified IC design layout. The mask can be formed in various technologies. In some embodiments, the mask is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask includes a transparent substrate (e.g., fused quartz) and an opaque material (e.g., chromium) coated in the opaque regions of the mask. In another example, the mask is formed using a phase shift technology. In the phase shift mask (PSM), various features in the pattern formed on the mask are configured to have proper phase difference to enhance the resolution and imaging quality. In various examples, the phase shift mask can be attenuated PSM or alternating PSM. The mask(s) generated by the mask fabrication 2234 is used in a variety of processes. For example, such a mask(s) is used in an ion implantation process to form various doped regions in the semiconductor wafer, in an etching process to form various etching regions in the semiconductor wafer, and/or in other suitable processes.

The IC fab 2240 is an IC fabrication entity that includes one or more manufacturing facilities for the fabrication of a variety of different IC products. In some embodiments, the IC fab 2240 is a semiconductor foundry. For example, there may be a first manufacturing facility for the front end fabrication of a plurality of IC products (e.g., source/drain structures, gate structures), while a second manufacturing facility may provide the middle end fabrication for the interconnection of the IC products (e.g., MDs, VDs, VGs) and a third manufacturing facility may provide the back end fabrication for the interconnection and packaging of the IC products (e.g., M0 tracks, M1 tracks, BM0 tracks, BM1 tracks), and a fourth manufacturing facility may provide other services for the foundry entity.

The IC fab 2240 uses the mask (or masks) fabricated by the mask house 2230 to fabricate the IC device 2260. Thus, the IC fab 2240 at least indirectly uses the IC design layout 2222 to fabricate the IC device 2260. In some embodiments, a semiconductor wafer is fabricated by the IC fab 2240 using the mask (or masks) to form the IC device 2260. The semiconductor wafer 2242 includes a silicon substrate or other proper substrate having material layers formed thereon. Semiconductor wafer further includes one or more of various doped regions, dielectric features, multilevel interconnects, and the like (formed at subsequent manufacturing steps).

The system 2200 is shown as having the design house 2220, mask house 2230, and IC fab 2240 as separate components or entities. However, it should be understood that one or more of the design house 2220, mask house 2230 or IC fab 2240 are part of the same component or entity.

In one aspect of the present disclosure, a method for fabricating semiconductor packages is disclosed. The method includes providing a semiconductor chip comprising a plurality of metallization layers disposed over a substrate and a plurality of first connector structures disposed on a topmost one of the plurality of metallization layers. The method includes forming a redistribution structure comprising a plurality of conductive layers and a plurality of via structures, adjacent ones of the plurality of conductive layers being connected through at least a corresponding one of the plurality of via structures. The method includes bonding the plurality of first connector structures to the redistribution structure. The method includes bonding the redistribution structure to a carrier substrate through a plurality of second connector structures. Forming the redistribution structure includes laterally rotating a first one of the plurality of via structures around a second one of the plurality of via structures, the first via structure being vertically above the second via structure.

In another aspect of the present disclosure, a non-transitory computer-readable media is disclosed. The computer-readable media includes computer-readable instructions stored thereon, that when executed by a processor cause the processor to identify a location of a first via structure connected to a first connector structure disposed on a first side of a redistribution structure. The instruction may further cause the processor to identify a location of a second via structure connected to a second connector structure disposed on a second side of the redistribution structure, the second side being opposite to the first side. The instruction may further cause the processor to determine, according to a first fixed direction, a location of a third via structure, wherein the first via structure and the third via structure extend downwardly and upwardly from a first conductive layer of the redistribution structure, respectively. The instruction may further cause the processor to determine, according to a second fixed direction, a location of a fourth via structure, wherein the third via structure and the fourth via structure extend downwardly and upwardly from a second conductive layer of the redistribution structure, respectively. The instruction may further cause the processor to determine, according to a preconfigured pattern, a location of a fifth via structure, wherein the fifth via structure and the second via structure extend downwardly and upwardly from a third conductive layer of the redistribution structure, respectively. The instruction may further cause the processor to adjust a location of a sixth via structure connecting a fourth conductive layer and a fifth conductive layer of the redistribution structure based on at least one of: (i) a location of a seventh via structure; or (ii) the location of the fourth or fifth via structure, wherein the fourth via structure and the sixth via structure extend downwardly and upwardly from the fourth conductive layer, respectively, the sixth via structure and the fifth via structure extend downwardly and upwardly from the fifth conductive layer, respectively, and the sixth and seventh via structures are laterally aligned with each other.

In another aspect of the present disclosure, a semiconductor device is disclosed. The semiconductor device includes a semiconductor chip comprising a plurality of metallization layers disposed over a substrate. The semiconductor device includes a carrier substrate. The semiconductor device includes a redistribution structure comprising a plurality of conductive layers and a plurality of via structures, wherein adjacent ones of the plurality of conductive layers are connected through at least a corresponding one of the plurality of via structures, and wherein the redistribution structure is coupled to the semiconductor chip and the carrier substrate through a plurality of first connector structures and a plurality of second connector structures. A first one of the plurality of via structures is disposed at a location being rotated around a second one of the plurality of via structures, the first via structure being vertically above or below the second via structure.

In another aspect of the present disclosure, a semiconductor device is disclosed. The semiconductor device includes a semiconductor chip comprising a plurality of metallization layers disposed over a substrate. The semiconductor device includes a redistribution structure comprising a plurality of conductive layers and a plurality of via structures, wherein adjacent ones of the plurality of conductive layers are connected through at least a corresponding via structure among the plurality of via structures. A first via structure among the plurality of via structures is disposed at a location being spaced from a second one of the plurality of via structures a same lateral distance as a third one of the plurality of via structures, the first via structure being vertically above or below the second via structure, and the third via structure. A conductive layer of the plurality of conductive layers comprises an octagonal element.

In another aspect of the present disclosure, a method for fabricating semiconductor packages is disclosed. The method includes forming a redistribution structure comprising a plurality of conductive layers and a plurality of via structures, adjacent ones of the plurality of conductive layers being connected through at least a corresponding one of the plurality of via structures. The method includes forming the redistribution structure further comprises laterally rotating a first via structure among the plurality of via structures around a second via structure among the plurality of via structures, the first via structure being above the second via structure.

In another aspect of the present disclosure, a method for manufacturing a semiconductor device is disclosed. The method includes identifying a location of a first via structure connected to a first connector structure disposed on a first side of a redistribution structure. The method includes identifying a location of a second via structure connected to a second connector structure disposed on a second side of the redistribution structure, the second side being opposite to the first side. The method includes determining, according to a first fixed direction, a location of a third via structure, wherein the first via structure and the third via structure are underneath and above of a first conductive layer of the redistribution structure, respectively. The method includes determining, according to a second fixed direction, a location of a fourth via structure, wherein the third via structure and the fourth via structure are underneath and above of a second conductive layer of the redistribution structure. The method includes determining, according to a preconfigured pattern, a location of a fifth via structure, wherein the fifth via structure and the second via structure are underneath and above of a third conductive layer of the redistribution structure, respectively. The method includes adjusting a location of a sixth via structure connecting a fourth conductive layer and a fifth conductive layer of the redistribution structure based on at least one of: (i) a location of a seventh via structure; or (ii) the location of the fourth or fifth via structure, wherein the fourth via structure and the sixth via structure the fourth conductive layer, respectively, the sixth via structure and the fifth via structure and the fifth conductive layer, respectively, and the sixth and seventh via structures are laterally aligned with each other.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for fabricating semiconductor packages, comprising:
forming a redistribution structure comprising a plurality of conductive layers and a plurality of via structures, adjacent ones of the plurality of conductive layers being connected through at least a corresponding one of the plurality of via structures;
wherein forming the redistribution structure further comprises laterally rotating a first via structure among the plurality of via structures around a second via structure among the plurality of via structures, the first via structure being above the second via structure.

2. The method of claim 1, further comprising:
laterally rotating the first via structure away from a third via structure among the plurality of via structures, the first and third via structures being laterally aligned with each other;
providing a semiconductor chip comprising a plurality of metallization layers disposed over a substrate and a plurality of first connector structures disposed on a topmost one of the plurality of metallization layers;
bonding the plurality of first connector structures to the redistribution structure; and
bonding the redistribution structure to a carrier substrate through a plurality of second connector structures.

3. The method of claim 2, wherein forming the redistribution structure further comprises laterally rotating the first via structure away from a fourth one of the plurality of via structures, the first and third via structures vertically disposed between the second via structure and the fourth via structure.

4. The method of claim 3, wherein the first via structure, the second via structure, and the fourth via structure belong to a first net, while the third via structure belongs to a second, different net.

5. The method of claim 3, wherein, subsequent to forming the redistribution structure, the first via structure is laterally spaced from any of the second, third, or fourth via structure with a spacing equal to or greater than a preconfigured threshold.

6. The method of claim 2, wherein the first and third via structures each connect a portion of a first conductive layer among the plurality of conductive layers to a portion of a second conductive layer among the plurality of conductive layers, the second via structure connects the portion of the first conductive layer to a portion of a third conductive layer among the plurality of conductive layers, and the fourth via structure connects the portion of the second conductive layer to a portion of a fourth conductive layer among the plurality of conductive layers.

7. The method of claim 6, wherein the redistribution structure further comprises a fifth conductive layer among the plurality of conductive layers, in which the fifth conductive layer, the third conductive layer, the first conductive layer, the second conductive layer, and the fourth conductive layer are vertically arranged in such an order from the first connector structures to the second connector structures.

8. The method of claim 6, wherein a first spacing between adjacent ones of the first connector structures is not proportional to a second spacing between adjacent ones of the second connector structures.

9. The method of claim 1, wherein forming the redistribution structure further comprises laterally rotating a fifth via structure among the plurality of via structures around a sixth via structure among the plurality of via structures, the fifth via structure being laterally aligned with the first and third via structures, the sixth via structure being aligned with the fourth via structure.

10. The method of claim 9, wherein the first to fourth via structure are configured to carry a first supply voltage, while the fifth to sixth via structures are configured to carry a second, different supply voltage.

11. A method for manufacturing a semiconductor device, comprising:
identifying a location of a first via structure connected to a first connector structure disposed on a first side of a redistribution structure;
identifying a location of a second via structure connected to a second connector structure disposed on a second side of the redistribution structure, the second side being opposite to the first side;
determining, according to a first fixed direction, a location of a third via structure, wherein the first via structure and the third via structure are underneath and above of a first conductive layer of the redistribution structure, respectively;
determining, according to a second fixed direction, a location of a fourth via structure, wherein the third via structure and the fourth via structure are underneath and above of a second conductive layer of the redistribution structure, respectively;
determining, according to a preconfigured pattern, a location of a fifth via structure, wherein the fifth via structure and the second via structure are underneath and above of a third conductive layer of the redistribution structure, respectively; and
adjusting a location of a sixth via structure connecting a fourth conductive layer and a fifth conductive layer of the redistribution structure based on at least one of: (i) a location of a seventh via structure; or (ii) the location of the fourth or fifth via structure, wherein the fourth via structure and the sixth via structure extend downwardly and upwardly from the fourth conductive layer, respectively, the sixth via structure and the fifth via structure extend downwardly and upwardly from the fifth conductive layer, respectively, and the sixth and seventh via structures are laterally aligned with each other.

12. The method of claim 11, further comprising:
rotating the location of the sixth via structure around the location of the fourth via structure and away from the location of the seventh via structure.

13. The method of claim 11, further comprising:
rotating the location of the sixth via structure around the location of the fourth via structure and away from the location of the fifth via structure.

14. The method of claim 11, further comprising:
rotating the location of the sixth via structure around the location of the fifth via structure and away from the location of the seventh via structure.

15. The method of claim 11, further comprising:
rotating the location of the sixth via structure around the location of the fifth via structure and away from the location of the fourth via structure.

16. The method of claim 11, wherein the first via structure, the first conductive layer, the third via structure, the second conductive layer, the fourth via structure, the fourth conductive layer, the sixth via structure, the fifth conductive layer, the fifth via structure, the third conductive layer, and the second via structure are vertically arranged in such an order from the first side to the second side.

17. The method of claim 11, wherein the first to sixth via structures belong to a first net, while the seventh via structure belongs to a second, different net.

18. The method of claim 11, wherein the first to seventh via structures are configured to carry a same supply voltage.

19. A semiconductor package, comprising:
a semiconductor chip comprising a plurality of metallization layers disposed over a substrate; and
a redistribution structure comprising a plurality of conductive layers and a plurality of via structures, wherein adjacent ones of the plurality of conductive layers are connected through at least a corresponding via structure among the plurality of via structures, wherein:
a first via structure among the plurality of via structures is disposed at a location being spaced from a second one of the plurality of via structures a same lateral distance as a third one of the plurality of via structures, the first via structure being vertically above or below the second via structure, and the third via structure; and
a conductive layer of the plurality of conductive layers comprises an octagonal element.

20. The semiconductor package of claim 19, further comprising:
a carrier substrate, wherein
the redistribution structure is coupled to the semiconductor chip and the carrier substrate through a plurality of first connector structures and a plurality of second connector structures, respectively; and
a first spacing between adjacent ones of the first connector structures is not proportional to a second spacing between adjacent ones of the second connector structures.
